(19) United States
(12) Patent Application Publication
(10) Pub. No.: US 2019/0172691 A1
(43) Pub. Date: Jun. 6, 2019

(54) HEATING CARRIER DEVICE FOR USE ON SPUTTERING CATHODE ASSEMBLY

(71) Applicant: NATIONAL CHUNG SHAN INSTITUTE OF SCIENCE AND TECHNOLOGY, TAOYUAN CITY (TW)

(72) Inventors: CHOU-YU LIN, TAOYUAN CITY (TW); HUI-YUN BOR, TAOYUAN CITY (TW); CHAO-NAN WEI, TAOYUAN CITY (TW); CHIEN-HUNG LIAO, TAOYUAN CITY (TW); SHEA-JUE WANG, TAIPEI (TW); SHIH-FAN CHEN, TAIPEI (TW)

(21) Appl. No.: 15/974,858

(22) Filed: May 9, 2018

(30) Foreign Application Priority Data
Dec. 4, 2017 (TW) 106142322

(51) Int. Cl. H01J 37/34

(52) U.S. Cl. CPC H01J 37/3497; H01J 2237/002; H01J 37/345; H01J 37/3435

(57) ABSTRACT

A heating carrier device for use on a sputtering cathode assembly has a heating carrier for heating a sputtering target to control a sputtering target temperature; a magnetic component for generating a magnetic field; a thermal insulation component disposed between the heating carrier and the magnetic component; and a cooling system for cooling the magnetic component. Therefore, the heating carrier device reduces the bonding strength of the sputtering target, reduces the particle size of sputtering products, and grows high-quality, uniform thin films.

### CROSS-REFERENCE TO RELATED APPLICATION

This non-provisional application claims priority under 35 U.S.C. § 119(a) on Patent Application No(s). 106142322 filed in Taiwan, R.O.C. on Dec. 4, 2017, the entire contents of which are hereby incorporated by reference.

### TECHNICAL FIELD

The present disclosure relates to heating carrier devices and, more particularly, to a heating carrier device for use on a sputtering cathode assembly.

### RELATED ART

Crucial and fundamental to plenty scientific and industrial applications, conventional thin-film sputtering technology requires a vacuum container to contain therein a parallel-panel thin-film sputtering device composed of a metallic sputtering target (cathode) and a substrate. An inert gas, such as helium, is introduced into the vacuum container. A DC voltage or high-frequency voltage is applied to the target to generate a vertical electric field on the surface of the target and thus generate discharge plasma in the vicinity of the target. Finally, an intended thin film is plated to the surface of the resultant plasma ions sputtering substrate.

To enhance the efficiency of effective plasma bombardment, the conventional thin film sputtering technology features providing a magnet module on the back of the target in a cathode assembly to increase the ionization rate of a sputtering gas and thin-film deposition speed. However, during a sputtering process, a magnet must be cooled in order to ensure its optimal performance. In view of this, conventional cathode assembly design requires a target to demonstrate a temperature difference across itself while being sputtering is taking place. As a result, stress is generated inside the target because of the temperature difference. Furthermore, material bonding inside the target is so energy-intensive that the bombarded material surface of the target looks like a rigid object's surface hit by bullets in terms of characteristics and distribution. The bombardment of the target produces plating products in the form of large atomic or molecular clusters and thus affects the glossiness and quality of the thin films thus deposited, or even the applicability thereof.

Therefore, related industrial sectors have to develop a target heating technology applicable to thin-film sputtering deposition to not only reduce the stress otherwise generated inside a target because of a temperature difference (so as to reduce greatly the chance that the internal structure of the target will be damaged by the stress and thereby extend the target's service life), but also improve the size of the clusters leaving the bombarded substances (to render the deposited thin films more delicate and enhance the uniformity, glossiness and characteristics of the deposited thin films.) Hence, a target heating technology applicable to thin-film sputtering deposition is important to magnetron sputtering-based thin film production technology.

### SUMMARY

In view of the aforesaid drawbacks of the prior art, it is an objective of the present disclosure to provide a heating carrier device for use on a sputtering cathode assembly. The present disclosure features integration of a heating carrier, a magnetic component, a thermal insulation component, and a cooling system. The thermal insulation component prevents deterioration of the magnetic component while the sputtering target is being heated. The heating carrier controls a sputtering target temperature, precludes a temperature difference across the sputtering target, prevents stress from being generated in the sputtering target, enables the sputtering target to stay at a control temperature, optimizes the size of the clusters emitted from the substance being bombarded, and enhances the uniformity, glossiness and characteristics of the deposited thin films.

In order to achieve the above and other objectives, the present disclosure provides a heating carrier device for use on a sputtering cathode assembly. The heating carrier device comprises: a heating carrier for heating a sputtering target to control a sputtering target temperature; a magnetic component for generating a magnetic field; a thermal insulation component disposed between the heating carrier and the magnetic component; and a cooling system for cooling the magnetic component.

Regarding the heating carrier device for use on a sputtering cathode assembly, the heating carrier has a temperature detection component for detecting the sputtering target temperature.

Regarding the heating carrier device for use on a sputtering cathode assembly, the heating carrier keeps the sputtering target at a control temperature ranging from room temperature to two-thirds of a melting point of a sputtering target material.

Regarding the heating carrier device for use on a sputtering cathode assembly, the cooling system cools the sputtering target.

Regarding the heating carrier device for use on a sputtering cathode assembly, the thermal insulation component is made of a ceramic material.

Regarding the heating carrier device for use on a sputtering cathode assembly, the cooling system is a water-cooled cooling system.

Regarding the heating carrier device for use on a sputtering cathode assembly, the magnetic component is a permanent magnet.

The above summary, the detailed description below, and the accompanying drawings further explain the technical means and measures taken to achieve predetermined objectives of the present disclosure and the effects thereof. The other objectives and advantages of the present disclosure are explained below and illustrated with the accompanying drawings.

### BRIEF DESCRIPTION OF THE DRAWINGS

FIG. 1 is a schematic view of a heating carrier device for use on a sputtering cathode assembly according to the first embodiment of the present disclosure;

FIG. 2 is a schematic view of the heating carrier device according to the second embodiment of the present disclosure;

FIG. 3 is a schematic view of the heating carrier device according to the third embodiment of the present disclosure;

FIG. 4 is a schematic view of the heating carrier device according to the fourth embodiment of the present disclosure; and

FIG. 5 are schematic views of a sputtering target's surface bombarded by argon ions at different temperatures, with view (a) depictive of an unheated sputtering target that produces large particle clusters, and view (b) depictive of a heated sputtering target that produces small particle clusters.

### DETAILED DESCRIPTION OF THE PREFERRED EMBODIMENTS

Fine structures and advantages of the present disclosure are described below with reference to preferred embodiments of the present disclosure to enable persons skilled in the art to gain insight into the technical features of the present disclosure.

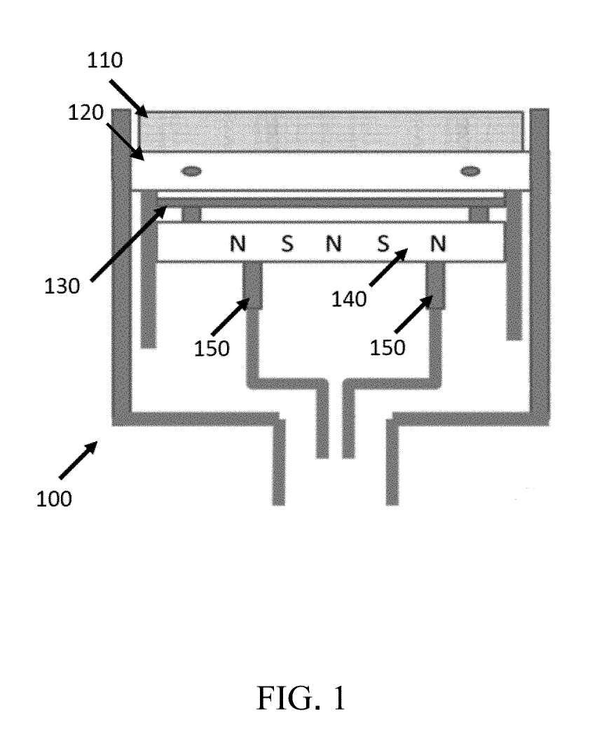

Referring to FIG. 1, in an embodiment of the present disclosure, a heating carrier device (100) for use on a sputtering cathode assembly comprises a heating carrier (120), a magnetic component (140), a thermal insulation component (130), and a cooling system (150). The heating carrier (120) heats a sputtering target (110) to control a sputtering target temperature. The sputtering target (110) is slender, cylindrical, or the like. The magnetic component (140) generates a magnetic field. The magnetic component (140) is a permanent magnet. However, in a variant embodiment, the magnetic component is an electromagnet or any other magnetic component. The thermal insulation component (130) is disposed between the heating carrier (120) and the magnetic component (140). The thermal insulation component is made of a ceramic material. However, in a variant embodiment, the thermal insulation component is made of fiberglass or made of any other material that renders it functionally unaffected even at the heating temperature of the heating carrier (120), but is not limited to this embodiment. The cooling system (150) cools the magnetic component (140) and is a water-cooled cooling system, but is not limited to this embodiment; in a variant embodiment, the cooling system is a gas-cooled cooling system or any other type of cooling device. During the sputtering process, the heating carrier (120) heats up the sputtering target (110) to an appropriate control temperature; however, despite the high temperature, fine structure of crystal grains in the sputtering target (110) neither moves out of position nor turns into any other structural phase. Afterward, the heat generated from the heating carrier (120) is kept out by the thermal insulation component (130). Hence, the magnetic component (140) retains its magnetic functionality (by staying cool) during a duty cycle while the sputtering target (110) is being heated.

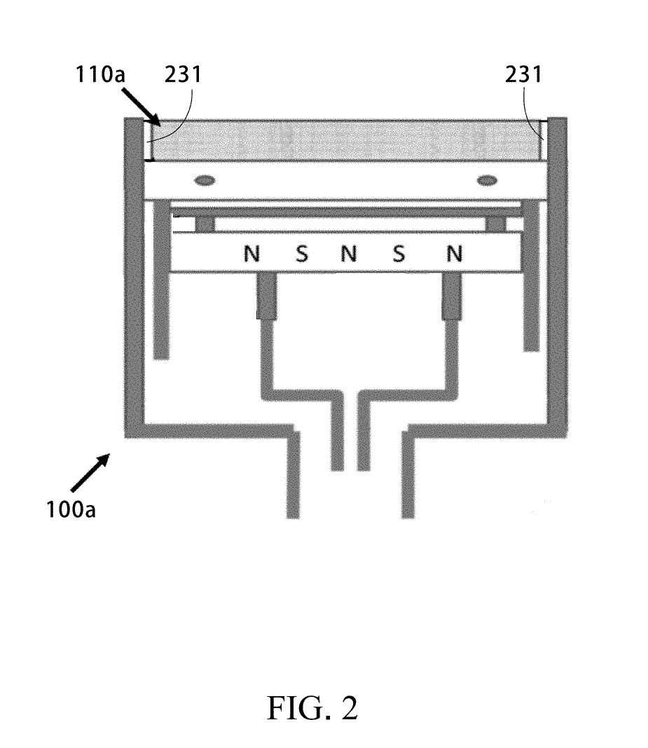

Referring to FIG. 2, there is shown a schematic view of the heating carrier device according to the second embodiment of the present disclosure. The heating carrier device (100a) of the second embodiment differs from the heating carrier device (100) of the first embodiment in functions and structure in that the heating carrier device (100a) further comprises two heat resistant components (231). The two heat resistant components (231) are attached to two ends of the sputtering target (110a), respectively, to stop heat from reaching the sputtering target (110a).

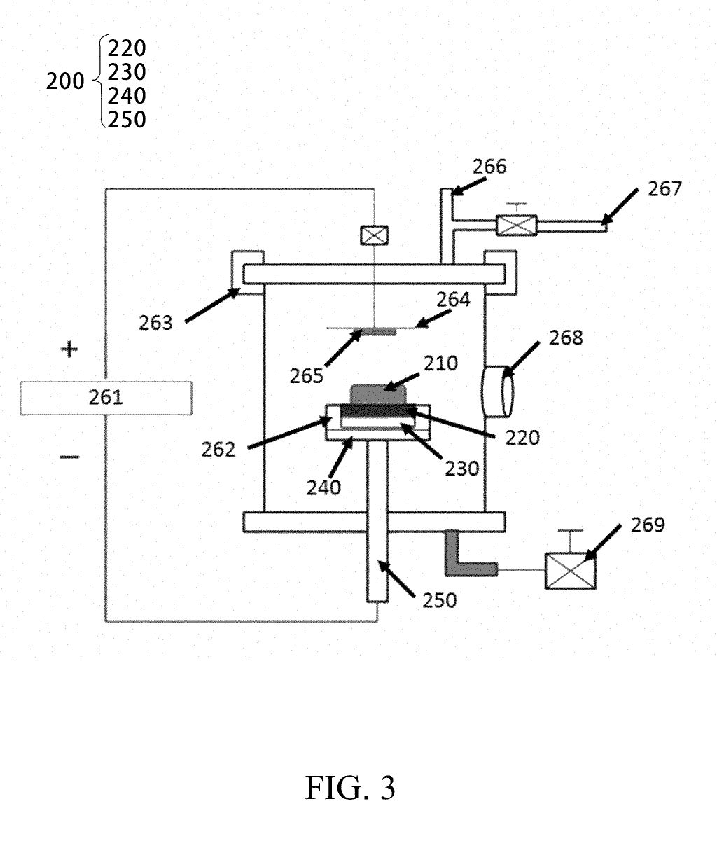

Referring to FIG. 3, there is shown a schematic view of the heating carrier device according to the third embodiment of the present disclosure. As shown in the diagram, a power system (261) supplies power. The anode of the power system (261) is connected to a cathode assembly (264). A cathode of the power system (261) is connected to a sputtering target (210). Both the cathode assembly (264) and the sputtering target (210) are made of a conductive metal, thereby allowing the cathode assembly (264) to carry positive charges and the sputtering target (210) to carry negative charges. The power system (261) further comprises a fixing device (263) for fixing an empty cavity in place. The empty cavity has therein the cathode assembly (264), the sputtering target (210), and a heating carrier device (200) for use on the sputtering cathode assembly. The heating carrier device (200) comprises a heating carrier (220), a thermal insulation component (230), a magnetic component (240) and a cooling system (250). Before the sputtering process starts, a vacuum system (269) removes air from the empty cavity to create a vacuum in the empty cavity. Then, a gas delivering pipe (267) introduces a specific working gas, such as argon (or any other inert gas) or oxygen, into the empty cavity. Afterward, a vacuum gauge (266) measures the pressure in the empty cavity. It is only when the vacuum gauge (266) shows the pressure in the empty cavity reaches an appropriate working pressure, say 10⁻³˜10⁻⁵ torr, that the sputtering process starts.

The sputtering target (210) is disposed on the heating carrier (220). The heating carrier (220) heats the sputtering target (210) and exercises temperature control. A thermal insulation component (230) is disposed below the heating carrier (220) to block the heat generated from the heating carrier (220). A protective layer (262) fixes the heating carrier (220) and the thermal insulation component (230) in place. The magnetic component (240) is disposed below the thermal insulation component (230) to attract and actuate argon to bombard the sputtering target (210). The cooling system (250) is disposed below the magnetic component (240) to cool the magnetic component (240) and thus ensure that the magnetic function thereof remains unabated. A sight glass (226) is disposed outside the empty cavity to enable observation of the sputtering process. The sputtering process involves placing below the cathode assembly (264) a substrate (265) to be sputtered, bombarding the sputtering target (210) with gas ions to generate a plurality of particle clusters, and depositing the plurality of particle clusters on the surface of the substrate (265) by the cathode assembly (264).

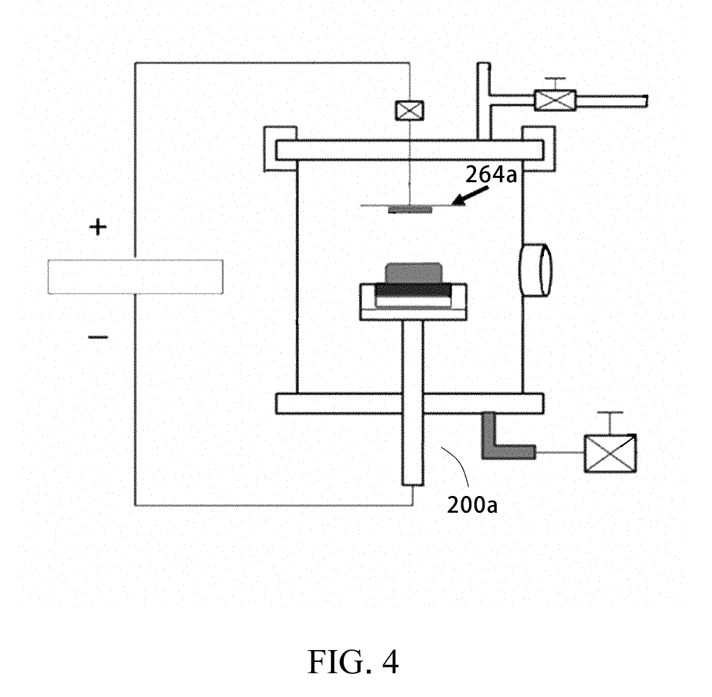

Referring to FIG. 4, there is shown a schematic view of the heating carrier device according to the fourth embodiment of the present disclosure. The heating carrier device (200a) of the fourth embodiment differs from the heating carrier device (200) of the third embodiment in functions and structure in that the heating carrier device (200a) further comprises an auxiliary cooling device (not shown). In the fourth embodiment, the auxiliary cooling device is disposed in the cathode assembly (264a) to cool the cathode assembly (264a). In the fourth embodiment, the auxiliary cooling device is a water-cooled cooling system. In a variant embodiment, the auxiliary cooling device is a gas-cooled cooling system or any other type of cooling device, but is not limited to this embodiment.

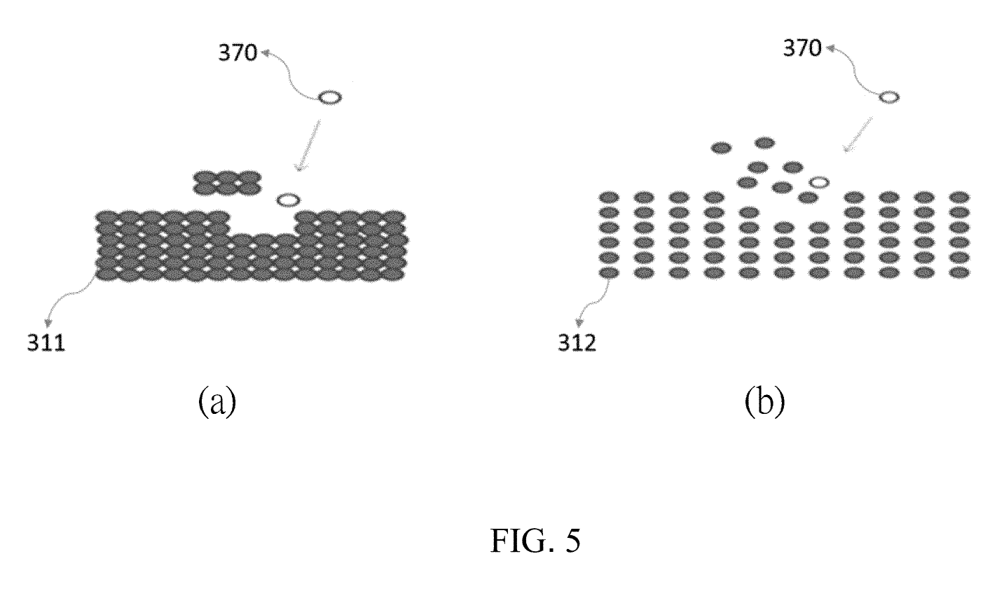

Referring to FIG. 5, during the sputtering process, argon ions (370) in plasma are subjected to an electric field, energized, and driven toward the cathode to therefore bombard the surface of an unheated sputtering target (311), causing the unheated sputtering target (311) to sputter. As shown in FIG. 5 (a), by the laws of thermodynamics, where a sputtering target stays at a high temperature below its melting point, its temperature indicates the average kinetic energy attributed to vibration of its lattice-confined atoms. The high temperature augments the vibration and thus destabilizes the atoms. The destabilized atoms have higher potential energy and form weaker bonds with each other. Hence, it is inferred that more atoms are ejected from a heated sputtering target (312) being bombarded by the argon ions (370) as shown in FIG. 5 (b), thereby enhancing sputtering efficiency and quality of the deposited thin films.

Under the aforesaid working pressure, the unheated sputtering target (311) has strong bonds between atoms and thus emits particles, among which particle clusters predominate and may be neutral or ionic. By contrast, the heated sputtering target (312) has weak bonds between atoms and thus emits particles, among which small particle clusters, single atoms, or ions predominate.

In an embodiment of the present disclosure, the heating carrier has a temperature detection component for detecting the temperature of the sputtering target. The sputtering target stays at a control temperature as soon as the heating carrier stops heating. The control temperature ranges from room temperature to two-thirds of the melting point of a sputtering target material, such as gold, copper, aluminum or titanium. The cooling system cools the sputtering target.

According to the prior art, a conventional magnetron sputtering cathode assembly is ineffective in cooling because of the presence of a magnet in a cathode assembly, whereas a sputtering target on the cathode assembly stays at low temperature during a sputtering process. As a result, the conventional magnetron sputtering cathode assembly fails to facilitate bombardment of plasma particles and resultant emission of particles. By contrast, the present disclosure improves the size of the clusters leaving the bombarded substances to render the deposited thin films more delicate and enhance the uniformity, glossiness and characteristics of the deposited thin films. Furthermore, by precluding a temperature gradient across the target, the present disclosure reduces the thermal stress inside the target and thus reduces the chance that the internal structure of the target will be damaged by the stress, thereby extending the target's service life.

The above embodiments are illustrative of the features and effects of the present disclosure rather than restrictive of the scope of the substantial technical disclosure of the present disclosure. Persons skilled in the art may modify and alter the above embodiments without departing from the spirit and scope of the present disclosure. Therefore, the scope of the protection of rights of the present disclosure shall be defined by the appended claims.

What is claimed is:

1. A heating carrier device for use on a sputtering cathode assembly, the heating carrier device comprising:
a heating carrier for heating a sputtering target to control a sputtering target temperature;
a magnetic component for generating a magnetic field;
a thermal insulation component disposed between the heating carrier and the magnetic component; and
a cooling system for cooling the magnetic component.

2. The heating carrier device of claim 1, wherein the heating carrier has a temperature detection component for detecting the sputtering target temperature.

3. The heating carrier device of claim 1, wherein the heating carrier keeps the sputtering target at a control temperature ranging from room temperature to two-thirds of a melting point of a sputtering target material.

4. The heating carrier device of claim 1, wherein the cooling system cools the sputtering target.

5. The heating carrier device of claim 1, wherein the thermal insulation component is made of a ceramic material.

6. The heating carrier device of claim 1, wherein the cooling system is a water-cooled cooling system.

7. The heating carrier device of claim 1, wherein the magnetic component is a permanent magnet.
